(19) United States
(12) Patent Application Publication
(10) Pub. No.: US 2025/0340993 A1
(43) Pub. Date: Nov. 6, 2025

(54) METHOD OF PROCESSING SUBSTRATE, METHOD OF MANUFACTURING SEMICONDUCTOR DEVICE, SUBSTRATE PROCESSING APPARATUS, AND RECORDING MEDIUM

(71) Applicant: Kokusai Electric Corporation, Tokyo (JP)

(72) Inventors: Yuji Takebayashi, Toyama-shi (JP); Hiroki Hatta, Toyama-shi (JP); Yunosuke Sakai, Toyama-shi (JP); Yusaku Okajima, Toyama-shi (JP)

(73) Assignee: Kokusai Electric Corporation, Tokyo (JP)

(21) Appl. No.: 19/271,519

(22) Filed: Jul. 16, 2025

Related U.S. Application Data
(63) Continuation of application No. PCT/JP2023/001225, filed on Jan. 17, 2023.

(51) Int. Cl. C23C 16/52; H01L 21/02

(52) U.S. Cl. CPC C23C 16/52; H01L 21/02271

(57) ABSTRACT

A technique includes (a) processing a substrate disposed in a process space by controlling a decomposition rate of a process gas supplied into the process space based on a predetermined relationship between the decomposition rate and a residence time of the process gas.

### CROSS-REFERENCE TO RELATED APPLICATION

This application is a Bypass Continuation Application of PCT International Application No. PCT/JP2023/001225, filed on Jan. 17, 2023, the disclosure of which is incorporated herein in its entirety by reference.

### TECHNICAL FIELD

The present disclosure relates to a method of processing a substrate, a method of manufacturing a semiconductor device, a substrate processing apparatus, and a recording medium.

### BACKGROUND

In the related art, as a step of a method of manufacturing a semiconductor device, a precursor gas and/or a reactant gas are supplied respectively for a supply time depending on an in-plane concentration distribution of by-products formed on a substrate.

However, when forming a film on the substrate, a high decomposition rate of a process gas may lead to deterioration in step coverage, while a low decomposition rate of the process gas may result in a reduction in a film formation rate.

### SUMMARY

The present disclosure provides a technique capable of controlling a decomposition rate of a process gas supplied to a substrate.

According to embodiments of the present disclosure, there is provided a technique that includes (a) processing a substrate disposed in a process space by controlling a decomposition rate of a process gas supplied into the process space based on a predetermined relationship between the decomposition rate and a residence time of the process gas.

### BRIEF DESCRIPTION OF DRAWINGS

The accompanying drawings, which are incorporated in and constitute a part of the specification, illustrate embodiments of the present disclosure.

FIG. 1 is a vertical cross-sectional view schematically illustrating a substrate processing apparatus according to embodiments of the present disclosure.

FIG. 2 is a vertical cross-sectional view illustrating details of a substrate support in FIG. 1.

FIG. 3A is a diagram illustrating a first gas supply system according to the embodiments of the present disclosure, FIG. 3B is a diagram illustrating a second gas supply system according to the embodiments of the present disclosure, and FIG. 3C is a diagram illustrating a third gas supply system according to the embodiments of the present disclosure.

FIG. 4A is a diagram illustrating a process chamber exhaust system according to the embodiments of the present disclosure, and FIG. 4B is a diagram illustrating a transfer chamber exhaust system according to the embodiments of the present disclosure.

FIG. 5 is a schematic configuration diagram of a controller of the substrate processing apparatus according to the embodiments of the present disclosure, illustrating a control system of the controller in a block diagram.

FIG. 6 is a diagram illustrating a substrate processing sequence according to the embodiments of the present disclosure.

FIG. 7 is a diagram illustrating a relationship between a residence time and a decomposition rate of a first gas.

FIG. 8 is a diagram illustrating a relationship between a flow velocity and the decomposition rate of the first gas.

FIG. 9A is a diagram illustrating a relationship between an elapsed time and a supply amount of the first gas, FIG. 9B is a diagram illustrating a relationship between the elapsed time and the residence time of the first gas, and FIG. 9C is a diagram illustrating a relationship between the elapsed time and the flow velocity of the first gas.

FIGS. 10A to 10C are diagrams illustrating examples of chemical structural formula of the first gas according to the embodiments of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

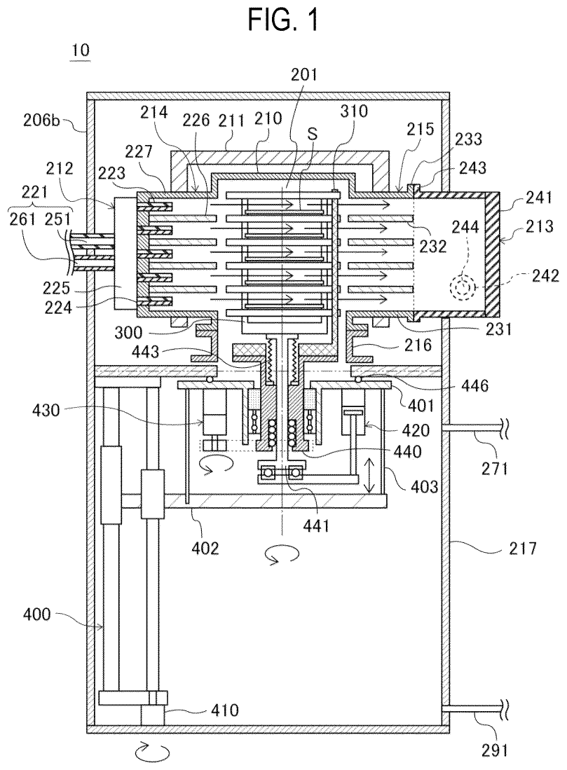

Hereinafter, embodiments of the present disclosure are described mainly with reference to FIGS. 1 to 10C. In addition, the drawings used in the following description are schematic, and dimensional relationships between respective components and proportions of respective components illustrated in the drawings may not correspond to those in reality. Further, the dimensional relationships between respective elements and the proportions of respective elements may not match among multiple drawings.

### (1) Configuration of Substrate Processing Apparatus

A configuration of a substrate processing apparatus 10 is described with reference to FIG. 1.

The substrate processing apparatus 10 includes a reaction tube storage chamber 206b, and inside the reaction tube storage chamber 206b, includes a cylindrical reaction tube 210 extending in a vertical direction, a heater 211 serving as a heating part (furnace) provided at an outer periphery of the reaction tube 210, a gas supply structure 212 serving as a gas supplier, and a gas exhaust structure 213 serving as a gas exhauster. The gas supplier may include an upstream rectifier 214 and nozzles 223 and 224 to be described later. Further, the gas exhauster may include a downstream rectifier 215 to be described later. A compartment of the reaction tube 210 in which a substrate S is processed is referred to as a process chamber 201. Further, the process chamber 201 may also be referred to as a process space inside which the substrate S is disposed.

The gas supply structure 212 is provided upstream of the reaction tube 210 in a gas flow direction, and a gas is supplied from the gas supply structure 212 into the reaction tube 210. The gas is supplied to the substrate S in a horizontal direction. The gas exhaust structure 213 is provided downstream of the reaction tube 210 in the gas flow direction, and the gas inside the reaction tube 210 is discharged from the gas exhaust structure 213. The gas supply structure 212, an interior of the reaction tube 210, and the gas exhaust structure 213 are in fluid communication with each other in the horizontal direction.

The upstream rectifier 214 is provided upstream of the reaction tube 210 between the reaction tube 210 and the gas supply structure 212 to regulate a flow of the gas supplied from the gas supply structure 212. Further, the downstream rectifier 215 is provided downstream of the reaction tube 210 between the reaction tube 210 and the gas exhaust structure 213 to regulate a flow of the gas to be discharged from the reaction tube 210. A lower end of the reaction tube 210 is supported by a manifold 216.

The reaction tube 210, upstream rectifier 214, and downstream rectifier 215 are formed in a continuous structure and are made of materials such as quartz or SiC, for example. These are configured as heat-permeable members that transmit heat radiated from the heater 211. The heat from the heater 211 heats the substrate S or the gas.

The gas supply structure 212 includes a distributor 225, which is connected to a gas supply pipe 251 and a gas supply pipe 261 and distributes a gas supplied from each gas supply pipe. A plurality of nozzles 223 and 224 are provided downstream of the distributor 225. The gas supply pipe 251 and the gas supply pipe 261 supply different types of gases as described later. The nozzles 223 and 224 are disposed in a vertical relationship or in a side-by-side relationship. In the present embodiments, the gas supply pipe 251 and the gas supply pipe 261 are also collectively referred to as a gas supply pipe 221. Each nozzle is also referred to as a gas discharger. The distributor 225 is configured to allow each gas to be supplied from the gas supply pipe 251 to the nozzle 223 and from the gas supply pipe 261 to the nozzle 224.

The upstream rectifier 214 includes a housing 227 and a partition 226. The partition 226 extends in the horizontal direction and is formed in a continuous structure without holes. The “horizontal direction” as used herein refers to a sidewall direction of the housing 227. A plurality of partitions 226 are disposed in the vertical direction. The partitions 226 are fixed to a sidewall of the housing 227 and are configured to prevent the gas from moving beyond the partitions 226 to a downward or upward adjacent region.

Each of the partitions 226 is provided at a position corresponding to each substrate S. The nozzles 223 and 224 are provided between the partitions 226 and between the partition 226 and the housing 227. A gas discharged from the nozzles 223 and 224 is regulated in gas flow by the partitions 226 and then supplied to a surface of the substrate S. In other words, the gas is supplied from a lateral side of the substrate S when viewed from the substrate S.

The downstream rectifier 215 is configured to be formed with a ceiling higher than the uppermost substrate S and to be formed with a bottom lower than the lowermost substrate S on the substrate support 300 in a state where the substrates S are supported by a substrate support 300 to be described later.

The downstream rectifier 215 includes a housing 231 and a partition 232. The partition 232 extends in the horizontal direction and is formed in a continuous structure without holes. The “horizontal direction” as used here refers to a sidewall direction of the housing 231. In addition, a plurality of partitions 232 are disposed in the vertical direction. The partitions 232 are fixed to a sidewall of the housing 231 and are configured to prevent the gas from moving beyond the partitions 232 to a downward or upward adjacent region. A flange 233 is provided at a side of the housing 231 that comes into contact with the gas exhaust structure 213.

Each of the partitions 232 is positioned to correspond to the substrate S and to correspond to the partition 226. The corresponding partitions 226 and 232 may be at an equal height. Further, when processing the substrate S, a height of the substrate S may be aligned with the height of the partitions 226 and 232.

By providing the partitions 226 and 232 to be in the above-described positional relationship, it is possible to make pressure loss uniform upstream and downstream of each substrate S in the vertical direction. In other words, it is possible to reliably create a horizontal gas flow, as indicated by the arrows in the drawing, with a suppressed vertical flow across the partition 226, a top of the substrate S, and the partition 232. Accordingly, it is possible to reduce a difference in a gas pressure on each substrate S. This enables uniform processing for each substrate S. Further, it is possible to reduce a difference in a residence time τ and/or a flow velocity v of a first gas, to be described later, on each substrate S. This may reduce a difference in a decomposition rate X of the first gas supplied to each substrate S.

The gas exhaust structure 213 is provided downstream of the downstream rectifier 215. The gas exhaust structure 213 mainly includes a housing 241 and an exhaust pipe connector 242. A flange 243 is provided at a side of the housing 241 toward the downstream rectifier 215. The housing 231 and the housing 241 are formed with a structure with continuous heights at ceilings and bottoms thereof. An exhaust hole 244 is formed downstream of the housing 241 in a downward direction or horizontal direction to discharge a gas passed through the downstream rectifier 215. The gas exhaust structure 213 is a lateral exhaust structure provided in a lateral direction of the reaction tube 210 to discharge the gas from the lateral direction of the substrate S.

A transfer chamber 217 is installed below the reaction tube 210 via the manifold 216. In the transfer chamber 217, the substrate S is placed (mounted) on the substrate support (hereinafter sometimes simply referred to as “boat”) 300 by a vacuum transport robot through a substrate loading port, or the substrate S is removed from the substrate support 300 by the vacuum transport robot.

The substrate support 300, a partition support 310, and a vertical driver 400 that drives the substrate support 300 and partition support 310 (collectively referred to as “substrate holder”) in both a vertical direction and a rotational direction may be stored in an interior of the transfer chamber 217. FIG. 1 illustrates a state where the substrate support 300 is raised by the vertical driver 400 and is stored in the reaction tube 210.

The vertical driver 400 includes a rotational driver 430 that rotates the substrate support 300 and the partition support 310 together and a boat up/down mechanism 420 that drives the substrate support 300 vertically relative to the partition support 310. The rotational driver 430 and the boat up/down mechanism 420 are fixed to a base flange 401, which serves as a lid supported on a base plate 402 by a side plate 403. A vacuum sealing O-ring 446 is installed on an upper surface of the base flange 401, and as illustrated in FIG. 1, is capable of maintaining the interior of the reaction tube 210 airtight by allowing an upper surface of the base flange 401 to be driven by a vertical drive motor 410 and raised to a position where the upper surface of the base flange 401 is pressed against the transfer chamber 217. A vacuum bellows 443 is connected between a support piece 440 fixed to the partition support 310 and a support piece 441 fixed to the substrate support 300.

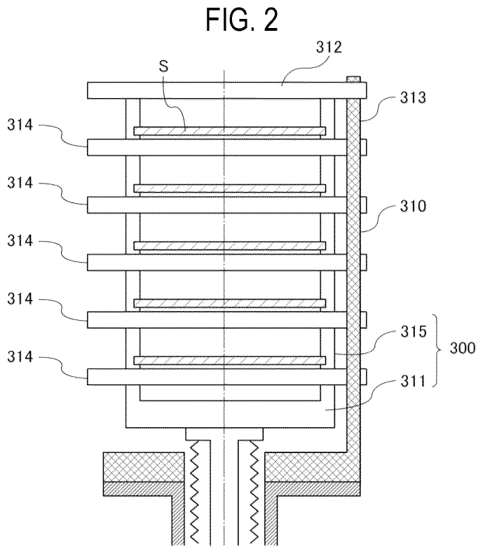

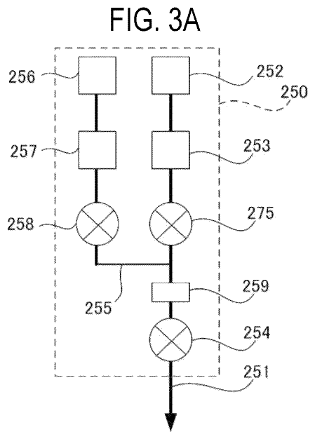

Next, details of the substrate support are described with reference to FIGS. 1 and 2.

The substrate support is configured as the substrate support 300 that supports at least the substrate S, and is stored inside the reaction tube 210. The substrate S is disposed immediately below an inner wall of a ceiling plate of the reaction tube 210. Further, the substrate support performs replacement of the substrate S by the vacuum transport robot through the substrate loading port (not illustrated) in the interior of the transfer chamber 217, or transports the replaced substrate S to the interior of the reaction tube 210 to perform formation of a thin film on the surface of the substrate S. The substrate loading port is provided, for example, at a sidewall of the transfer chamber 217. In addition, the substrate support may be considered to include the partition support 310.

A plurality of substrates S are placed on the substrate support 300 at a predetermined interval in the vertical direction (perpendicular direction) by a plurality of support rods 315 supported on a base 311. A space between the plurality of substrates S supported by the support rods 315 is partitioned by disc-shaped partitions 314 fixed (supported) at a predetermined interval to a pillar 313 supported by the partition support 310. Herein, the partitions 314 are located immediately below the substrates S, and located either or both above and below the substrates S. The partitions 314 obstruct the space between the respective substrates S. The predetermined interval between the plurality of substrates S placed on the substrate support 300 is the same as the vertical interval between the partitions 314 fixed to the partition support 310. Further, a diameter of the partition 314 is larger than a diameter of the substrate S.

The base 311, the partitions 314, and the plurality of support rods 315 are made of materials such as quartz or SiC, for example. In addition, an example of supporting five substrates S on the substrate support 300 is illustrated herein, but the present disclosure is not limited thereto. For example, the substrate support 300 may be configured to be capable of supporting approximately 5 to 50 substrates S. In addition, the partition 314 is also referred to as a separator.

In addition, the notation of numerical ranges such as “5 to 50” herein implies that the lower limit value and the upper limit value are included in that range. Thus, for example, “5 to 50 sheets” implies “5 sheets or more and 50 sheets or less.” The same is applied to other numerical ranges.

In a step of forming a thin film on the substrate S, the partition 314 may be positioned at a height corresponding to the partition 226 and/or the partition 232. More particularly, the heights of the partitions 314, 226 and 232 may be aligned.

By using such a substrate support, it becomes easier to create a horizontal gas flow with a suppressed vertical flow across the partition 226, the top of the substrate S, and the partition 232. This results in a uniform difference in the gas pressure on each substrate S, allowing for uniform processing on each substrate S. Further, it is possible to reduce a difference in the residence time τ and/or the flow velocity v of the first gas to be described later on each substrate S. This may reduce a difference in the decomposition rate X of the first gas supplied to each substrate S.

The partition support 310 and the substrate support 300 are driven by the vertical driver 400 in the vertical direction between the reaction tube 210 and the transfer chamber 217 and in the rotational direction around a center of the substrate S supported by the substrate support 300.

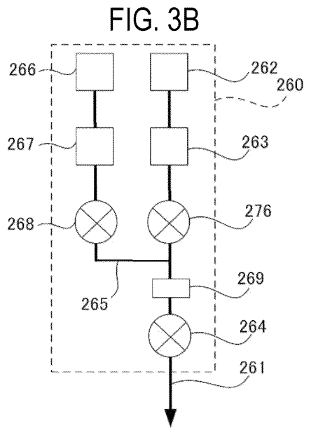

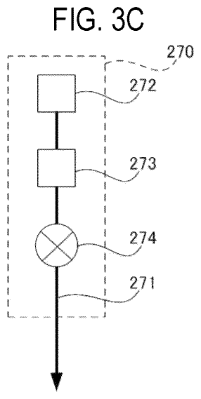

Next, details of a gas supply system are described with reference to FIGS. 3A to 3C.

As illustrated in FIG. 3A, the gas supply pipe 251 is provided in upstream order with a first gas source 252, a mass flow controller (MFC) 253 serving as a flow rate controller, a valve 275 serving as an on/off valve, a tank 259 serving as a reservoir for storing a gas, and a valve 254 serving as an on/off valve.

The first gas source 252 is a source of the first gas containing a first element (also referred to as “first element-containing gas”). The first gas is a precursor gas, i.e., one of process gases.

A first gas supply system 250 (also referred to as “precursor gas supply system” or “process gas supply system”) mainly includes the gas supply pipe 251, MFC 253, valve 275, tank 259, and valve 254. The first gas source 252 may also be included in the first gas supply system 250.

A gas supply pipe 255 is connected to the gas supply pipe 251 between the valve 275 and the tank 259. The gas supply pipe 255 is provided in upstream order with an inert gas source 256, an MFC 257, and a valve 258 serving as an on/off valve. An inert gas is supplied from the inert gas source 256.

A first inert gas supply system mainly includes the gas supply pipe 255, MFC 257, and valve 258. The inert gas supplied from the inert gas source 256 acts as a purge gas that purges a gas remaining inside the reaction tube 210 in a substrate processing step. The inert gas source 256 may also be included in the first inert gas supply system. The first inert gas supply system may be added to the first gas supply system 250.

As illustrated in FIG. 3B, the gas supply pipe 261 is provided in upstream order with a second gas source 262, an MFC 263, a valve 276, a tank 269, and a valve 264.

The second gas source 262 is a source of a second gas containing a second element (also referred to as “second element-containing gas”). The second gas is a different gas from the first gas and may be one of process gases. In addition, the second gas may be considered as a reactant gas that reacts with a precursor of the first gas, which is the precursor gas, or as a modifying gas that modifies the surface of the substrate S.

A second gas supply system 260 (also referred to as “reaction gas supply system” or “process gas supply system”) mainly includes the gas supply pipe 261, MFC 263, valve 276, tank 269, and valve 264. The second gas source 262 may also be included in the second gas supply system 260.

A gas supply pipe 265 is connected to the gas supply pipe 261 between the valve 276 and the tank 269. The gas supply pipe 265 is provided in upstream order with an inert gas source 266, an MFC 267, and a valve 268 serving as an on/off valve. An inert gas is supplied from the inert gas source 266.

A second inert gas supply system mainly includes the gas supply pipe 265, MFC 267, and valve 268. The inert gas supplied from the inert gas source 266 acts as a purge gas that purges a gas remaining inside the reaction tube 210 in a substrate processing step. The inert gas source 266 may also be included in the second inert gas supply system. The second inert gas supply system may be added to the second gas supply system 260.

As illustrated in FIG. 3C, a gas supply pipe 271 is provided in upstream order with a third gas source 272, an MFC 273, and a valve 274. The gas supply pipe 271 is connected to the transfer chamber 217. An inert gas is supplied when changing the transfer chamber 217 to an inert gas atmosphere, or when changing the transfer chamber 217 to a vacuum state.

The third gas source 272 is an inert gas source. A third gas supply system 270 mainly includes the gas supply pipe 271, MFC 273, and valve 274. The third gas source 272 may also be included in the third gas supply system 270. The third gas supply system 270 is also referred to as a transfer chamber supply system.

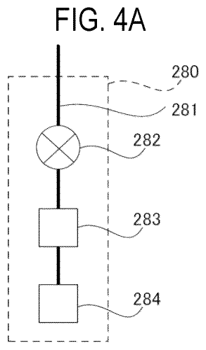

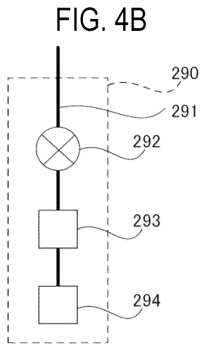

Next, an exhaust system is described with reference to FIGS. 4A and 4B.

An exhaust system 280, which vacuum-exhausts an atmosphere of the reaction tube 210, includes an exhaust pipe 281 that is in fluid communication with the reaction tube 210, and is connected to the housing 241 via the exhaust pipe connector 242.

As illustrated in FIG. 4A, the exhaust pipe 281 is connected to a vacuum pump 284, serving as a vacuum exhauster, via a valve 282 and an auto pressure controller (APC) valve 283 serving as a pressure regulator (pressure regulation part), and is configured to vacuum-exhaust the reaction tube 210 to a predetermined pressure (vacuum degree). The exhaust pipe 281, valve 282, and APC valve 283 are collectively referred to as the exhaust system 280. The exhaust system 280 is also referred to as a process chamber exhaust system. In addition, the vacuum pump 284 may also be included in the exhaust system 280. An exhaust system 290, which vacuum-exhausts an atmosphere of the transfer chamber 217, is connected to the transfer chamber 217, and includes an exhaust pipe 291 that is in fluid communication with the interior of the transfer chamber 217.

As illustrated in FIG. 4B, the exhaust pipe 291 is connected to a vacuum pump 294 via a valve 292 and an APC valve 293, and is configured to vacuum-exhausts the transfer chamber 217 to a predetermined pressure. The exhaust pipe 291, valve 292, and APC valve 293 are collectively referred to as the exhaust system 290. The exhaust system 290 is also referred to as a transfer chamber exhaust system. In addition, the vacuum pump 294 may also be included in the exhaust system 290.

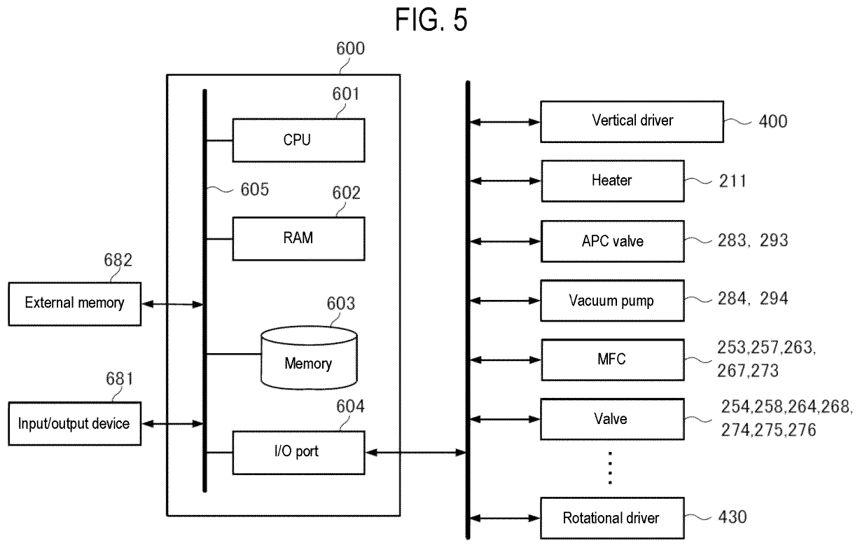

Next, a controller, which is a control part (control means), is described with reference to FIG. 5. The substrate processing apparatus 10 includes a controller 600 that controls the operation of each component of the substrate processing apparatus 10.

The controller 600 is schematically illustrated in FIG. 5. The controller 600 is configured as a computer including a central processing unit (CPU) 601, a random access memory (RAM) 602, a memory 603, and an I/O port 604. The RAM 602, memory 603, and I/O port 604 are configured to be capable of exchanging data with the CPU 601 via an internal bus 605.

The memory 603 is configured as, for example, a flash memory, a hard disk drive (HDD), or others. The memory 603 stores, in a readable manner, a control program for controlling the operation of the substrate processing apparatus 10, a process recipe containing procedures, conditions and others of substrate processing, and others.

In addition, the process recipe is a combination that executes each of the procedures in the substrate processing steps to be described later in the controller 600 so as to obtain predetermined results. The process recipe functions as a program. Hereinafter, the process recipe, control program, and others are collectively referred to simply as “program.” In addition, the “program” as used herein may include a case of solely including the process recipe, a case of solely including the control program, or a case of including both. Further, the RAM 602 is configured as a memory area (work area) in which programs, data, and others read by the CPU 601 are temporarily held.

The I/O port 604 is connected to the above-described vertical driver 400, heater 211, APC valves 283 and 293, vacuum pumps 284 and 294, and MFCs 253, 257, 263, 267 and 273, valves 254, 258, 264, 268, 274, 275 and 276, rotational driver 430, and others.

The CPU 601 is configured to read and execute the control program from the memory 603 and to read the process recipe from the memory 603 in response to an input of an operation command and the like from an input/output device 681. Then, the CPU 601 is configured to control, according to contents of the process recipe thus read, a lifting operation of the substrate support 300 by the vertical driver 400, a heating operation by the heater 211, opening/closing operations of the APC valves 283 and 293, start and stop of the vacuum pumps 284 and 294, flow rate regulation operations of various gases by the MFCs 253, 257, 263, 267 and 273, opening/closing operations of the valves 254, 258, 264, 268, 274, 275 and 276, rotation and rotational speed regulation operations of the substrate support 300 by the rotational driver 430, and others.

The controller 600 according to the present embodiment may be configured, for example, by installing a program to a computer by using an external memory (e.g., a magnetic disk such as a hard disk, an optical disk such as a DVD, a magneto-optical disk such as an MO, and a semiconductor memory such as a USB memory) 682 storing the above-described program. Further, a way for supplying the program to the computer is not limited to supplying it through the external memory 682. For example, the program may be supplied using a communication means such as the Internet or a dedicated line without the external memory 682. In addition, the memory 603 or the external memory 682 is configured as a computer-readable recording medium storing the program. Hereinafter, these are collectively referred to simply as “recording medium.” In addition, the “recording medium” as used herein may include a case of solely including the memory 603, a case of solely including the external memory 682, or a case of including both.

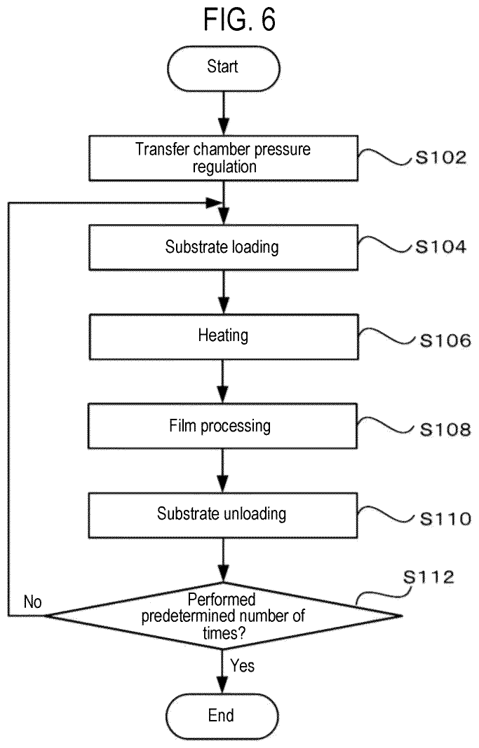

Next, a step of forming a thin film on the substrate S by using the substrate processing apparatus 10 of the above-described configuration is described as one of semiconductor manufacturing steps with reference to FIGS. 6 to 10C. In addition, in the following description, the operation of each component constituting the substrate processing apparatus 10 is controlled by the controller 600.

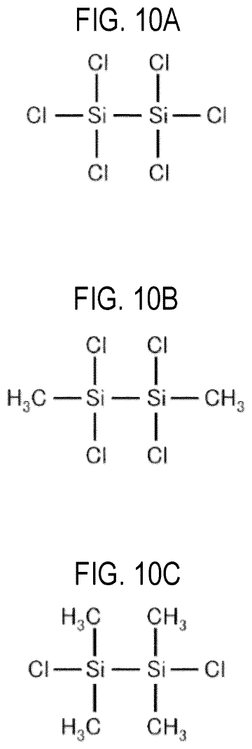

Herein, a film formation process for forming a film in a recess such as a trench or hole in the substrate S by using the first gas and the second gas is described. For example, a hexachlorodisilane (Si₂Cl₆, abbreviation: HCDS) gas represented in FIG. 10A may be used as the first gas.

The term “substrate” as used herein may refer to the substrate itself or a stack of the substrate and a predetermined layer or film formed on a surface of the substrate. The “surface of the substrate” as used herein may refer to the surface of the substrate itself, or a surface of a predetermined layer or the like formed on the substrate. When it is stated herein “forming a predetermined layer on the substrate,” it may refer to directly forming a predetermined layer or the like on the surface of the substrate itself or forming a predetermined layer on a layer or the like formed on the substrate. When the “wafer” is used herein, it is also synonymous with the “substrate.”

### (S102)

A transfer chamber pressure regulation step S102 is described. Herein, an internal pressure of the transfer chamber 217 is set to the same level pressure as that of a vacuum transport chamber (not illustrated) adjacent to the transfer chamber 217. Specifically, the exhaust system 290 is activated to vacuum-exhaust the atmosphere of the transfer chamber 217 so that the atmosphere of the transfer chamber 217 reaches a vacuum level.

### (S104)

Next, a substrate loading step S104 is described.

Once the transfer chamber 217 reaches the vacuum level, transport of the substrate S begins. When the substrate S arrives at the vacuum transport chamber, a gate valve is opened, and the vacuum transport robot loads the substrate S into the transfer chamber 217.

At this time, the substrate support 300 is on standby inside the transfer chamber 217, and the substrate S is transferred onto the substrate support 300. Once a predetermined number of substrates S are transferred onto the substrate support 300, the vacuum transport robot is retracted, and the substrate support 300 is raised by the vertical driver 400 to move the substrates S into the reaction tube 210. At this time, the surface of the substrate S is positioned to align with the heights of the partitions 226 and 232.

### (S106)

Next, a heating step S106 is described. Once the substrate S is loaded into the reaction tube 210, the interior of the reaction tube 210 is controlled to a predetermined pressure, and a surface temperature of the substrate S is controlled to a predetermined temperature. When using, for example, a HCDS gas as a first gas, a temperature of the heater 211 may be controlled such that a temperature of the substrate S reaches, for example, 100 to 1500 degrees C., particularly, 200 to 1000 degrees C., and more particularly 400 to 800 degrees C. Further, an internal pressure of the reaction tube 210 may be set to, for example, 5 to 100 kPa.

### (S108)

Next, a film processing step S108 is described. In the film processing step S108, a predetermined film is formed on the substrate S, whose surface includes recesses, according to the process recipe by performing, one or more times, a first gas supply step in which the first gas is flash-supplied to the substrate S and a second gas supply step in which the second gas is flash-supplied to the substrate S, as described later.

### <First Gas Supply Step, Step S1>

In this step, the first gas is flash-supplied to the process chamber 201 inside which the substrate S is disposed. Herein, the “flash-supply” refers to supplying a large flow rate of gas into the reaction tube 210 within a short time.

Specifically, in this step, the first gas is stored in advance in the tank 259 provided on the gas supply pipe 251. When using, for example, a HCDS gas as the first gas, an internal pressure of the tank 259 at this time may be set, for example, to 100 to 100×10³ Pa, particularly to 1.0×10³ to 80×10³ Pa, and more particularly to 5.0×10³ to 60×10³ Pa.

Then, when supplying the first gas, the valve 254 provided downstream of the tank 259 between the tank 259 and the nozzle 223 is opened, so that the first gas is supplied into the gas supply pipe 251 from the tank 259 in which the first gas is stored in advance. At this time, an internal pressure (total pressure) of the process chamber 201 is set, for example, to 10 to 1.0×10³ Pa. Then, once a predetermined time is passed after beginning the supply of the first gas, the valve 254 is closed to stop the supply of the first gas into the gas supply pipe 251. When using, for example, a HCDS gas as the first gas, the valve 254 is closed to stop the supply of the first gas into the gas supply pipe 251 after a time, for example, within a range of 0.1 to 10 seconds is passed.

After a large amount of the first gas is supplied from the gas supply structure 212 into the reaction tube 210 through the upstream rectifier 214 within a short time, the first gas is exposed and subsequently discharged through the space above the substrate S, the downstream rectifier 215, the gas exhaust structure 213, and the exhaust pipe 281. At this time, the valve 282 and the APC valve 283 are in an open state. Herein, the valve 275 may be in an open state or a closed state while supplying the first gas into the process chamber 201.

At this time, a decomposition rate of the first gas inside the process chamber 201 changes within a range of 0% to 100% according to a change in the residence time τ of the first gas. Herein, in the case where the decomposition rate includes 0%, the decomposition rate of 0% means that there is no temporal change in the decomposition rate of the first gas. In other words, the decomposition rate of 0% refers to a state where the first gas supplied into the process chamber 201 is discharged from the process chamber 201 in the same state as it was supplied. Further, the decomposition rate of 100% refers to a state where the first gas supplied into the process chamber 201 is completely discharged from the process chamber 201 in a form other than the first gas. The same is also applied to the following description.

Herein, a residence time of a gas refers to a numerical indicator of a time from when the gas is supplied into the process chamber 201 until it is discharged from the process chamber 201. In the following description, the residence time of the first gas is defined as a time from when the first gas is supplied into the process chamber 201 until it is discharged from the process chamber 201. Further, the residence time may be defined as a numerical indicator of a time from when any gas is supplied into the process chamber 201 until it is discharged from the process chamber 201. Further, the residence time may be defined as a numerical indicator of a time from when any gas reaches the process space until it leaves the process space.

In the following description, the residence time of the first gas is defined as a time from when the first gas reaches the top of the substrate S until it leaves the top of the substrate S. Alternatively, the residence time of the first gas may be defined, for example, as a time from when the first gas reaches the process space until it escapes from the process space. Further, the residence time of the first gas may also be defined as a time from when the first gas is discharged from the gas supplier such as the nozzle 223 until it reaches the exhaust hole 244. Further, the residence time of the first gas may be a time from the start to the end of supply of the first gas, such as a time from when the valve 254 at the downstream of the tank 259 is opened until the valve 254 is closed, which corresponds to a time from a start or an end of a predetermined operation by a predetermined component of the substrate processing apparatus 10 to a start or an end of the predetermined operation. Further, the residence time may be calculated by dividing the diameter of the substrate S by the flow velocity of the first gas on the substrate S. Further, the residence time may be calculated by dividing a volume of the process chamber 201 by a volume of gas discharged from the process chamber 201 per unit time. Further, the residence time may be defined as a time needed for the number of molecules of the first gas inside the process chamber to be reduced to a predetermined value.

In this step, the residence time τ of the first gas is set according to the decomposition rate X of the first gas, based on a predetermined relationship between the residence time τ of the first gas inside the process chamber 201 and the decomposition rate X of the first gas inside the process chamber 201. That is, the decomposition rate X of the first gas supplied to the substrate S is controlled by controlling the residence time τ of the first gas.

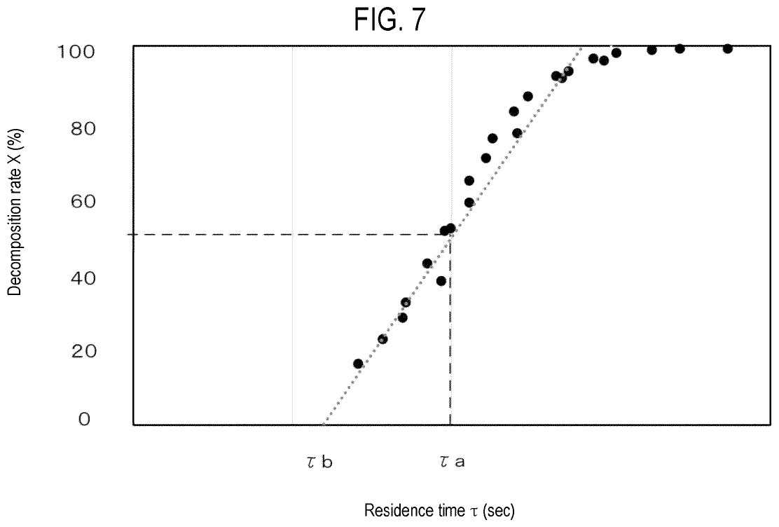

Herein, a relationship between the residence time τ(seconds) and the decomposition rate X (%) of the first gas inside the process chamber 201 at a predetermined pressure within a range of 10 to 1.0x10³ Pa is described with reference to FIG. 7. FIG. 7 is a semi-logarithmic graph in which the horizontal axis represents the residence time τ (seconds) of the first gas on a logarithmic scale, and the vertical axis represents the decomposition rate X (%) of the first gas.

As illustrated in FIG. 7, the decomposition rate X of the first gas increases logarithmically as the residence time τ inside the process chamber 201 becomes longer. Herein, according to FIG. 7, for example, by setting the residence time τ of the first gas to be τa, it is possible to supply the first gas to the substrate S with a decomposition rate X of 50%. Further, by setting the residence time τ of the first gas to be τa or less, it is possible to supply the first gas to the substrate S with a decomposition rate X of 50% or less. Further, by setting the residence time τ of the first gas to be τb or less, it is possible to supply the first gas to the substrate S with a decomposition rate X close to 0%. That is, the decomposition rate may be controlled based on a predetermined relationship between the decomposition rate and the residence time of the first gas inside the process space. In other words, the decomposition rate may be predicted based on a predetermined relationship between the decomposition rate and the residence time of the first gas inside the process space under a certain condition.

In other words, by setting the residence time τ of the first gas to be a value equal to or less than a first time τ1, at which a value of the decomposition rate X becomes a first decomposition rate X1, it is possible to control the value of the decomposition rate X to be within a range (first range) of the first decomposition rate X1 or less. That is, by setting the residence time τ of the first gas to be below a predetermined value, it is possible to make the decomposition rate of the first gas lower than a decomposition rate of the first gas when the residence time τ of the first gas is set at the predetermined value. Further, by setting the residence time τ of the first gas to be a value equal to or less than a second time τ2, which is longer than the first time τ1 and at which the value of the decomposition rate X becomes a second decomposition rate X2 higher than the first decomposition rate X1, it is possible to control the value of the decomposition rate X to be within a range (second range) of the second decomposition rate X2 or less. That is, by setting the residence time τ of the first gas to be beyond a predetermined value, it is possible to make the decomposition rate of the first gas higher than a decomposition rate of the first gas when the residence time τ of the first gas is set at the predetermined value.

Herein, the residence time τ of the first gas inside the process chamber 201 may be controlled by controlling the flow velocity v of the first gas inside the process chamber 201. That is, increasing (i.e., speeding up) the flow velocity v of the first gas may shorten the residence time of the first gas inside the process chamber 201. Further, decreasing (i.e., slowing down) the flow velocity v of the first gas may lengthen the residence time of the first gas inside the process chamber 201.

Herein, a flow velocity of a gas refers to a numerical indicator of a distance that the gas supplied into the process chamber 201 moves per unit time. Further, it may refer to a numerical indicator of a distance that the gas moves per unit time inside the process chamber 201. Further, it may be refer to a numerical indicator of a distance that the gas moves per indicator unit time inside the process space.

In the following description, the flow velocity v of the first gas refers to an average flow velocity of the first gas on the substrate S. Alternatively, the flow velocity v of the first gas may be an average flow velocity of the first gas from a certain location (or region) to another location (or region) such as an average flow velocity from the time the first gas is discharged from the gas supplier such as the nozzle 223 into the process chamber 201 until it reaches the exhaust hole 244. Further, an average flow velocity of the first gas inside the process space may be used as the flow velocity v of the first gas. Further, an average flow velocity of the first gas inside the process chamber 201 may be used as the flow velocity v of the first gas. Further, instead of the average flow velocity of the first gas in the above-described example, a flow velocity of the first gas at any point on the substrate S, inside the process space, or inside the process chamber 201 may be used as the flow velocity v of the first gas.

Further, the residence time or flow velocity of the first gas as described above may be a measured, calculated or estimated value obtained by using any methods, or a value derived from simulation.

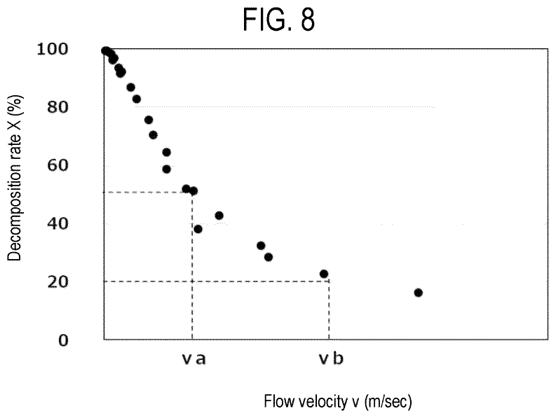

Herein, a relationship between the flow velocity v (m/sec) and the decomposition rate X (%) of the first gas inside the process chamber 201 at a predetermined pressure within the range of 10 to 1.0×10³ Pa is described with reference to FIG. 8. In FIG. 8, the horizontal axis represents the flow velocity v (m/sec) of the first gas, and the vertical axis represents the decomposition rate X (%) of the first gas.

As illustrated in FIG. 8, the decomposition rate X of the first gas gradually decreases as the flow velocity v inside the process chamber 201 increases. Herein, according to FIG. 8, for example, by setting the flow velocity v of the first gas to be va, it is possible to supply the first gas to the substrate S with a decomposition rate X of 50%. Further, by setting the flow velocity v of the first gas to be va or greater, it is possible to supply the first gas to the substrate S with a decomposition rate X of 50% or less. That is, the decomposition rate may be controlled based on a predetermined relationship between the decomposition rate and the flow velocity of the first gas inside the process space. In other words, the decomposition rate may be predicted based on a predetermined relationship between the decomposition rate and the flow velocity of the first gas inside the process space under a certain condition.

In other words, by setting the flow velocity v of the first gas to be equal to or greater than a first flow velocity v1, it is possible to supply the first gas to the substrate S with a decomposition rate X equal to or less than a first decomposition rate X1. That is, by setting the flow velocity v of the first gas to be greater than a predetermined value, it is possible to make the decomposition rate of the first gas lower than a decomposition rate of the first gas when the flow velocity v of the first gas is at the predetermined value. Further, by setting the flow velocity v of the first gas to be equal to or greater than a second flow velocity v2 smaller than the first flow velocity v1, it is possible to supply the first gas to the substrate S with a decomposition rate X equal to or less than a second decomposition rate X2 higher than the first decomposition rate X1. That is, by setting the flow velocity v of the first gas to be below a predetermined value, it is possible to make the decomposition rate of the first gas higher than a decomposition rate of the first gas when the flow velocity v of the first gas is at the predetermined value.

When using a HCDS gas, for example, as the first gas, the decomposition rate X of the first gas may be within a range of 0% to 100% by controlling the residence time τ of the first gas in this step to fall within a range of 1.00 to 0.01 seconds. Further, the decomposition rate X may be within a range of 50% to 100% by controlling the residence time τ to fall within a range of 1.00 to 0.10 seconds. Further, the decomposition rate X may be within a range of 0% to 50% by controlling the residence time τ to fall within a range of 0.10 to 0.01 seconds. Further, the decomposition rate X may be 0%, i.e., the first gas may remain undecomposed by controlling the residence time τ to 0.01 seconds or less. Further, the decomposition rate X may be 100% by setting the residence time τ to be greater than 1.00 seconds.

When using a HCDS gas, for example, as the first gas, the decomposition rate X of the first gas may be within a range of 0% to 50% by controlling the flow velocity v of the first gas in this step to be 5.0 m/sec or more. Further, the decomposition rate X may be within a range of 0% to 25% by controlling the flow velocity v of the first gas, for example, to be 10 m/sec or more. Further, the decomposition rate X may be within a range of 0% to 15% by controlling the flow velocity v of the first gas, for example, to be 15 m/sec or more. Further, the decomposition rate X may be 0%, i.e., the first gas may remain undecomposed by controlling the residence time τ to be 20.0 m/sec or more. Further, the decomposition rate X may be within a range of 50% to 100% by setting the residence time τ to be below 5.0 m/sec.

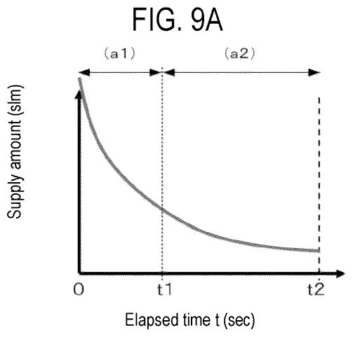

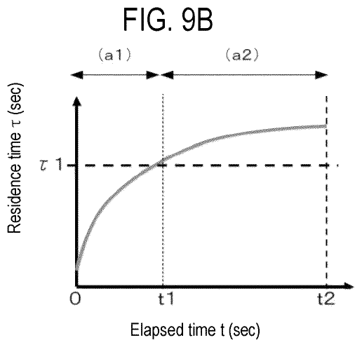

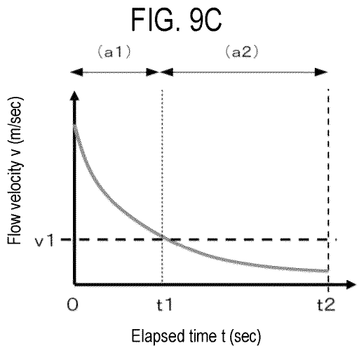

Herein, FIGS. 9A, 9B and 9C are diagrams schematically illustrating temporal changes in a supply amount, the residence time τ, and the flow velocity v of the first gas, respectively, inside the process chamber 201 in this step.

In the following description, in this step, a period from the start of supply of the first gas until t1 seconds is referred to as an inrush area a1, and a period from t1 seconds to t2 seconds is referred to as an exposure area a2. The end time t1 of the inrush area a1 and the end time t2 of the exposure area a2 are set appropriately according to a process target or process content. As illustrated in FIG. 9A, the supply amount of the first gas is maximum at the start of supply of the first gas, and then, rapidly decreases in the inrush area a1. Subsequently, the supply amount of the first gas gradually decreases in the exposure area a2. Further, as illustrated in FIG. 9B, the residence time of the first gas rapidly increases in the inrush area a1, and then, gradually increases in the exposure area a2. Further, as illustrated in FIG. 9C, the flow velocity of the first gas is the highest (high flow velocity) at the start of supply of the first gas, and then rapidly decreases in the inrush area a1. Subsequently, the flow velocity of the first gas gradually decreases in the exposure area a2.

In the inrush area a1, the first gas flows in a relatively high flow velocity, which may shorten the residence time of the first gas inside the process chamber 201. That is, based on the relationship between the residence time of the first gas and the decomposition rate X of the first gas as illustrated in FIG. 7, it is possible to supply the first gas to the substrate S with a low decomposition rate within a first range such as 0% to 50%, particularly 0% to 15%, and more particularly 0%.

Further, in the inrush area a1, the flow velocity of the first gas is relatively high and the supply amount of the first gas is also relatively high. In other words, a large flow rate of the first gas is supplied within a short time from the start of supply of the first gas. In this way, an adsorption amount of either or both of the process gas and a first-element-containing substance as described later, which is adsorbed on the surface of the substrate S, increases for a period from when reaction by-products as described later are generated until they are adsorbed on the surface of the substrate S. This may enhance a film formation rate. Further, an amount of the first gas that reaches a deep side of the recess within a short time from the start of supply of the first gas increases. Thus, the adsorption amount of either or both of the process gas and the first-element-containing substance increases for the period from when the reaction by-products are generated until they are adsorbed on the substrate S. This may enhance step coverage.

Further, when forming a film in the recess (or groove, trench, hole) formed in the substrate S, a higher reactivity of a gas increases adsorption ease to an opening side of the recess, but makes it more difficult for the gas to be adsorbed on the deep side of the recess. Therefore, when using, as the first gas, a gas that generates a highly reactive substance by decomposition (e.g., HCDS gas) so as to form a film in the recess, shortening the residence time τ of the above-described first gas and/or increasing the flow velocity v of the first gas may lower the decomposition rate X, thereby enhancing the step coverage. In addition, controlling the residence time τ of the first gas and/or the flow velocity v of the first gas to achieve the decomposition rate X of 0% for the first gas may be desired to enhance the step coverage. In addition, controlling the residence time τ of the first gas and/or the flow velocity v of the first gas to achieve the decomposition rate X of 0% for the first gas in at least a portion of the inrush area a1 may be desired to enhance the step coverage.

When using, for example, a HCDS gas as the first gas, setting the flow velocity of the first gas, for example, to 10 m/sec or more in the inrush area a1 may lower the decomposition rate X to a relatively low value within a range of 0% to 25%, which is favorable for enhancing the step coverage. Further, setting the flow velocity of the first gas, for example, to 15 m/sec or more may further lower the decomposition rate to a range of 0% to 15%, which is even more desirable for enhancing the step coverage. Furthermore, controlling the flow velocity to 20.0 m/sec or more may achieve the decomposition rate of 0%, indicating that the first gas remains undecomposed, which is more desirable for enhancing the step coverage. Further, in the inrush area a1, the film formation rate may be controlled by setting the flow velocity of the first gas, for example, to a range of 5 to 10 m/sec to achieve a decomposition rate X within a range of 25% to 50%.

Further, the first gas flows in a low flow velocity in the exposure area a2, which may lengthen the residence time of the first gas inside the process chamber 201. That is, based on the relationship between the residence time of the first gas and the decomposition rate X of the first gas as illustrated in FIG. 7, it is possible to supply the first gas to the substrate S with a high decomposition rate within a second range such as 15% to 100%, particularly 25% to 100%, and more particularly 50% to 100%. Thus, the film formation rate may be controlled based on the decomposition rate X.

When using a HCDS gas, for example, as the first gas, the decomposition rate of the first gas in the exposure area a2 may be, for example, 50% or more when the flow velocity of the first gas is 5.0 m/sec or less, 25% or more when the flow velocity of the first gas is 10 m/sec or less, and 15% or more when the flow velocity of the first gas is 15 m/sec or less. Thus, the film formation rate may be controlled based on the decomposition rate X.

That is, in this step, it is possible to change the decomposition rate X of the first gas supplied to the substrate S by flash-supplying the first gas. Further, by flash-supplying the first gas in this step, the flow velocity of the first gas is controlled, which in turn controls the residence time of the first gas inside the process chamber 201, thereby enabling control of the decomposition rate X of the first gas.

Further, in this step, it is possible to increase the supply amount of the first gas at the start of supply of the first gas by flash-supplying the first gas. When using a HCDS gas, for example, as the first gas, a supply amount of the first gas per unit time for each substrate S may be controlled, for example, 0.001 to 15 slm, particularly to 0.05 to 10 slm, and more particularly to 0.010 to 5slm. Decreasing the supply amount below 0.001 slm may result in a reduction in a partial pressure of the first gas inside the process chamber 201, leading to a reduction in the film formation rate. Increasing the supply amount beyond 15 slm may result in an increase in the partial pressure of the first gas inside the process chamber 201, leading to an excessive progression of the decomposition of the first gas. The supply amount of 0.001 to 15 slm allows for a change in the flow velocity of the first gas by flow rate control while preventing a reduction in the film formation rate and an excessive decomposition of the first gas. Further, the supply amount of 0.05 to 10 slm allows for a change in the flow velocity of the first gas by flow rate control while further preventing a reduction in the film formation rate and an excessive decomposition of the first gas. The supply amount of 0.010 to 5 slm allows for a change in the flow velocity of the first gas by flow rate control while sufficiently preventing a reduction in the film formation rate and an excessive decomposition of the first gas.

In addition, by flash-supplying the first gas, it is possible to supply a high pressure first gas, pressurized inside the tank 259, into the process chamber 201. This allows for an increase in the flow velocity of the first gas at the start of supply.

That is, this step includes controlling the decomposition rate X of the first gas to the first range such as 0% to 25%, and controlling the decomposition rate X of the first gas to the second range such as 25% to 100%. Further, in this step, by the flash supply of the first gas, a high decomposition rate supply with a long residence time of the first gas is consecutively performed after a low decomposition rate supply with a short residence time of the first gas. Thus, it is possible to supply the first gas with different decomposition rates in succession, thereby preventing adsorption of reaction by-products and others on adsorption sites during purge or exhaust of the process chamber 201. Further, by performing the high decomposition rate supply after the low decomposition rate supply of supplying a large amount of a gas within a short time, it is possible to prevent the adsorption of the reaction by-products as described later on the adsorption sites.

In this way, step coverage performance may be enhanced in the step of controlling the decomposition rate X of the first gas to fall within the first range, while the film formation rate may be enhanced in the step of controlling the decomposition rate X of the first gas to fall within the second range, which is at least partially different from the first range. That is, it is possible to achieve both the enhanced step coverage performance and the enhanced film formation rate.

Further, as described above, in this step, the valve 282 and the APC valve 283 are in the open state, and while supplying the first gas into the process chamber 201, the reaction tube 210 is vacuum-exhausted by the vacuum pump 284. Thus, the internal pressure of the process chamber 201 is lowered and the flow velocity of the first gas is increased, allowing for a shortened residence time τ of the first gas inside the process chamber 201.

Further, while supplying the first gas into the process chamber 201, the valve 258 may be opened to flow a low molecular weight gas with a smaller molecular weight than that of the first gas into the gas supply pipe 251 through the gas supply pipe 255. That is, a mixed process gas in which the low molecular weight gas and the first gas are mixed may be supplied to the process chamber 201. Herein, the low molecular weight gas may be a gas exhibiting a low reactivity with the first gas. Further, an inert gas may be used as the low molecular weight gas. Further, in order to prevent the first gas from entering the gas supply pipe 261, the valves 268 and 264 may be opened to flow an inert gas into the gas supply pipe 261. In this case, the inert gas supplied from the gas supply pipe 261 may also be considered as a part of the mixed process gas.

Herein, the low molecular weight gas may be, for example, nitrogen (N₂), helium (He), or argon (Ar), etc.

By using the mixed process gas, an average molecular weight of the gas supplied in this step may be reduced. When the mixed process gas and the first gas are supplied under the same conditions with equal kinetic energy, the mixed process gas with a smaller average molecular weight achieves a higher flow velocity than the first gas. Thus, a flow velocity of the mixed process gas may be made higher than the flow velocity of the first gas.

Herein, an amount of the low molecular weight gas in the mixed process gas may be, for example, 50 times or less. If the amount is greater than 50 times that of the first gas, the partial pressure of the first gas inside the process chamber 201 decreases due to the increased proportion of the low molecular weight gas in the mixed process gas, potentially resulting in a reduction in the film formation rate and the step coverage. If the amount of the low molecular weight gas in the mixed process gas is 50 times or less of the amount of the first gas in the mixed process gas, it is possible to control the flow velocity of the first gas while minimizing the effect of a reduction in the partial pressure of the first gas. Further, if the amount of the low molecular weight gas in mixed process gas is, for example, 40 times or less, the effect of a reduction in the partial pressure of the first gas is further minimized. Further, for example, if it is 30 times or less, the effect of a reduction in the partial pressure of the first gas is significantly further minimized, allowing for control over the decomposition rate while preventing a reduction in the step coverage even in the recess with a high aspect ratio.

Further, in at least a part of this step, a volume of the first gas supplied into the process chamber 201 per unit time may be set to 0.0005 to 6 times, particularly 0.0015 to 3 times, and more particularly 0.0030 to 1 time the volume of the process chamber 201. Decreasing the volume below 0.0005 times may result in a reduction in the partial pressure of the first gas inside the process chamber 201, leading to a reduction in the film formation rate. Increasing the volume beyond 6 times may result in an increase in the partial pressure of the first gas inside the process chamber 201, leading to an excessive progression of the decomposition of the first gas. Setting the volume to 0.0005 to 6 times allows for a change in the flow velocity of the first gas by flow rate control while effectively preventing a reduction in the film formation rate and an excessive decomposition of the first gas. Further, setting the volume to 0.0015 to 3 times allows for a change in the flow velocity of the first gas by flow rate control while further preventing a reduction in the film formation rate and an excessive decomposition of the first gas. Setting the volume to 0.0030 to 1 time allows for a change in the flow velocity of the first gas by flow rate control while sufficiently preventing a reduction in the film formation rate and an excessive decomposition of the first gas.

Further, in at least a part of this step, a volume of the first gas discharged from the process chamber 201 per unit time may be set to 50 to 4000 times, particularly 100 to 2000 times, and more particularly 300 to 1000 times the volume of the process chamber 201. Decreasing the volume of the first gas below 50 times may shorten a time until the internal pressure of the process chamber 201 rises after the start of supply of the first gas, making it difficult to maintain a high flow velocity of the first gas. As a result, it may be difficult to control the decomposition rate of the first gas to remain at a low level (e.g., a state where the decomposition rate of the first gas is 25% or less, 15% or less, or 0% or less) for a certain time. Increasing the volume of the first gas beyond 4000 times may result in a reduction in the partial pressure of the first gas inside the process chamber 201, leading to a reduction in the film formation rate. If the volume of the first gas is set to 50 to 4,000 times, it becomes easier to control the decomposition rate of the first gas to remain at a low level for a certain time while preventing a reduction in the film formation rate of the first gas. Further, if the volume of the first gas is set to 100 to 2000 times, it is easier to further control the decomposition rate of the first gas to remain at a low level for a certain time while further preventing a reduction in the film formation rate of the first gas. Further, if the volume of the first gas is set to 300 to 1000 times, it becomes easier to sufficiently control the decomposition rate of the first gas to remain at a low level for a certain time while sufficiently preventing a reduction in the film formation rate of the first gas.

Further, the APC valve 283 may be regulated to vacuum-exhaust the reaction tube 210 by the vacuum pump 284 before this step and before the start of supply of the first gas into the process chamber 201. This may increase the flow velocity of the first gas, particularly the flow velocity at the start of supply, i.e., the flow velocity in the above-described inrush area, thus shortening the residence time τ of the first gas inside the process chamber 201.

Further, an internal temperature of the process chamber 201 in this step may be set higher than a decomposition temperature of the first gas. This may enhance the film deposition rate by increasing a reactivity of the first gas, and may also prevent an increase in the decomposition rate of the first gas by shortening the residence time of the first gas inside the process chamber 201.

This step may be performed such that at least a portion of the adsorption sites on the surface of the substrate S are converted into first element sites where a substance containing a first element included in the first gas, i.e., the first-element-containing substance is chemically adsorbed.

In the above-described embodiments, for example, silicon (Si) and germanium (Ge), which are group 14 elements, and aluminum (Al), gallium (Ga), and indium (In), which are group 13 elements, may be used as the first element. Further, for example, a transition metal element may be used as the first element. For example, the transition metal element such as titanium (Ti), zirconium (Zr), and Hf (hafnium), which are group 4 elements, niobium (Nb) and tantalum (Ta), which are group 5 elements, molybdenum (Mo) and tungsten (W), which are group 6 elements, manganese (Mn), which is a group 7 element, ruthenium (Ru), which is a group 8 element, cobalt (Co), which is a group 9 element, and nickel (Ni), which is a group 10 element, and others may be used as the first element.

For example, a Si-containing gas that contains Si as the first element may be used as the first gas. An example of the Si-containing gas may include a Si and chlorine (Cl)-containing gas. For example, a precursor gas or the like containing a Si-Si bond, such as a HCDS gas described in FIG. 10A or the like, may be used as the Si and Cl-containing gas. As illustrated in FIG. 10A, a HCDS gas contains Si and a chloro group (chloride) in the chemical structural formula thereof (in one molecule). Further, for example, 1,1,2,2-tetrachloro-1,2-dimethyldisilane ((CH₃)₂Si₂Cl₄, abbreviation: TCDMDS) or 1,2-dichloro-1,1,2,2-tetramethyldisilane ((CH₃)₄Si₂Cl₂, abbreviation: DCTMDS) may be used as the Si and Cl-containing gas. TCDMDS, as described in FIG. 10B, contains a Si—Si bond and further contains a chloro group and an alkylene group. Further, DCTMDS, as described in FIG. 10C, contains a Si—Si bond and further contains a chloro group and an alkylene group. One or more of these may be used as the first gas.

As for the inert gas, for example, N₂ gas of noble gases such as Ar gas, He gas, Ne gas, and Xe gas may be used. One or more of these gases may be used as the inert gas. The same is also applied to each step to be described later.

In the case of using, for example, a HCDS gas as the first gas, a Si—Si bond is cleaved when the HCDS gas is decomposed, resulting in generation of SiCl₄ and SiCl₂ with higher reactivity compared to the HCDS gas. In other words, the HCDS gas is decomposed as follows.

HCDS(Si₂Cl₆)→SiCl₄+SiCl₂

Since SiCl₄ and SiCl₂ possess higher reactivity compared to HCDS, a decomposition rate of HCDS is high, and the reaction progresses as the decomposition of HCDS progresses. Then, when using, for example, an ammonia (NH₃) gas as a second gas to be described later, SiCl₂ and SiCl₄ react respectively with an NH group to be described later to form a SiN layer. At this time, reaction by-products such as hydrogen chloride (HCl) are generated.

At least a portion of the adsorption sites on the surface of the substrate S are converted into Si sites where a Si-containing substance is chemically adsorbed, but the reaction by-products such as HCl are adsorbed on the adsorption sites on the substrate S, preventing the adsorption of the Si-containing substance. In this step, a large amount of the first gas is supplied to the substrate S within a short time from the start of supply by flash-supplying the first gas, and this reduces the adsorption sites on the substrate S for the reaction by-products such as HCl, thus increasing an adsorption amount of the Si-containing substance. This allows for the enhanced film formation rate and step coverage performance.

### <Purge, Step S2>

In this step, a purge gas is supplied to the process chamber 201 inside which the substrate S is disposed. In other words, after the flash-supply of the first gas in step S1, the Si-containing substance that was not adsorbed on the adsorption sites removed from the interior of the reaction tube 210 or the reaction by-products that were re-adsorbed on the surface of the substrate S are desorbed and removed from the interior of the reaction tube 210.

Specifically, while the valve 254 is in an open state, the valve 275 is closed and the valves 258, 268, and 264 are opened to supply an inert gas serving as the purge gas into the gas supply pipes 251 and 261 through the gas supply pipes 255 and 265, and at the same time, the valve 282 and the APC valve 283 on the exhaust pipe 281 remain open, so that the interior of the reaction tube 210 is vacuum-exhausted by the vacuum pump 284.

### <Second Gas Supply Step, Step S3>

Next, a second gas that reacts with the first gas is supplied to the process chamber 201 inside which the substrate S is disposed. Specifically, in this step, the second gas is stored in advance in the tank 269 provided at the gas supply pipe 261. Then, when supplying the second gas, the valve 264 provided downstream of the tank 269 between the tank 269 and the nozzle 224 is opened, so that the second gas is supplied into the gas supply pipe 261 from the tank 269 in which the second gas is stored in advance. Then, once a predetermined time is passed after the start of supply of the second gas, the valve 264 is closed to stop the supply of the second gas into the gas supply pipe 261.

A large amount of the second gas is supplied from the gas supply structure 212 into the reaction tube 210 through the upstream rectifier 214 within a short time, and is then exposed and subsequently discharged through the space above the substrate S, the downstream rectifier 215, the gas exhaust structure 213, and the exhaust pipe 281. At this time, the valve 282 and the APC valve 283 are in the open state. Herein, the valve 276 may be in an open state or a closed state while supplying the second gas into the process chamber 201. Further, the valve 268 may be opened to flow an inert gas such as N₂ gas into the gas supply pipe 261 through the gas supply pipe 265. Further, to prevent the second gas from entering the gas supply pipe 251, the valves 258 and 254 may be opened to flow an inert gas into the gas supply pipe 251. At this time, a large amount of the second gas is supplied at once in the horizontal direction from the lateral side of the substrate S to the substrate S through the gas supply structure 212 that is in fluid communication with the reaction tube 210.

In addition, the internal temperature of the process chamber 201 at this time may be set higher than a decomposition temperature of the second gas. Further, as in step S1 described above, a decomposition rate X of the second gas in this step may be controlled by setting a residence time τ of the second gas based on a predetermined relationship between the decomposition rate X of the second gas inside the process chamber 201 and the residence time τ of the second gas inside the process chamber 201.

As for the second gas, for example, a gas that is different from the first gas and containing a second element may be used. The second element is, for example, one of N, oxygen (O), and carbon (C). For example, a hydrogen (H) and N-containing gas may be used as the second gas. Examples of the H and N-containing gas may include a hydrogen nitride-based gas containing a N—H bond such as ammonia (NH₃) gas, diazene (N₂H₂) gas, hydrazine (N₂H₄) gas, and N₃H₈ gas. One or more of these may be used as the second gas.

### <Purge, Step S4>

In this step, by the same process procedure as in step S2, a purge gas is supplied to the process chamber 201 inside which the substrate S is disposed. In other words, after flash-supplying the second gas in step S3, the second gas that was not adsorbed on the adsorption sites are removed from the interior of the reaction tube 210 or reaction by-products that were generated by the reaction with the second gas and were re-adsorbed on the surface of the substrate S are desorbed and removed from the interior of the reaction tube 210.

Specifically, while the valve 264 is in an open state, the valve 276 is closed and the valves 268, 258 and 254 are opened to supply an inert gas serving as the purge gas into the gas supply pipes 251 and 261 through the gas supply pipes 255 and 265, and at the same time, the valve 282 and the APC valve 283 on the exhaust pipe 281 remain open such that the interior of the reaction tube 210 is vacuum-exhausted by the vacuum pump 284. This may prevent a reaction between the first gas and the second gas existing in the air inside the reaction tube 210.

### (Performed Predetermined Number of Times)

A film with a predetermined thickness is formed on the substrate S with a recess by performing a cycle a predetermined number of times (n times, n is an integer of 1 or more), the cycle including performing the above-described first gas supply step and second gas supply step sequentially and non-simultaneously. When using, for example, a HCDS gas as the first gas and the H and N-containing gas as the second gas, a SiN film is formed. This allows for the formation of a film on the substrate S with the recess while achieving an enhanced step coverage performance and increased film formation rate.

### (S110)

Next, a substrate unloading step S110 is described. In S110, the processed substrate S is unloaded out of the transfer chamber 217 in the reverse procedure of the above-described substrate loading step S104.

### (S112)

Next, determination S112 is described. Herein, it is determined whether or not the substrate is processed a predetermined number of times. If it is determined that the substrate is not processed the predetermined number of times, the process returns to the substrate loading step S104 and the next substrate S is processed. If it is determined that the substrate is processed the predetermined number of times, the process is terminated.

In addition, the formation of the gas flow is described as horizontal in the above, but the gas flow may be diffused vertically as long as a main gas flow is formed in the overall horizontal direction and as long as the uniform processing of a plurality of substrates is not affected.

Further, it goes without saying that the expressions such as the same degree, equivalent, equal, and others used in the above are substantially the same.

### Other Embodiments

The embodiments of the present disclosure are specifically described above, but the present disclosure is not limited thereto, and may be modified in various ways without departing from the spirit thereof.

In the above-described embodiments, the case with the tank 259 provided in the above-described first gas supply system 250 is described, but the present disclosure is not limited thereto. In other words, in the first gas supply system 250, the tank 259 may not be provided and the first gas may be supplied by a method other than the flash supply. In this case as well, the same effects as those of the above-described embodiments are obtained.

Similarly, the case with the tank 269 provided in the above-described second gas supply system 260 is described, but the embodiments of the present disclosure are not limited thereto. In other words, in the second gas supply system 260, the tank 269 may not be provided and the second gas may be supplied by a method other than the flash supply. In this case as well, the same effects as those of the above-described embodiments are obtained.

Further, in the above-described embodiments, the case where a film is formed on the substrate S by using the first gas and the second gas in the film formation process performed by the substrate processing apparatus is described by way of example, but the embodiments of the present disclosure are not limited thereto. In other words, other types of gases may be used as the process gases to be used in the film formation process to thereby form other types of thin films. Furthermore, the embodiments of the present disclosure may be applied even when three or more types of process gases are used.

Further, in the above-described embodiments, the film formation process is described by way of example as a process performed by the substrate processing apparatus, but the embodiments of the present disclosure are not limited thereto. In other words, the present disclosure may be applied to a film formation process other than the film formation process mentioned in the above-described embodiments.

Further, in the above-described embodiments, an example of forming a film by using a batch-type substrate processing apparatus capable of processing a plurality of substrates at once is described. The present disclosure is not limited to the above-described embodiments, and for example, may be suitably applied even when forming a film by using a single-wafer type substrate processing apparatus capable of processing one or several substrates at once. Further, in the above-described embodiments, an example of forming a film by using a substrate processing apparatus equipped with a hot-wall type process furnace is described. The present disclosure is not limited to the above-described embodiments, and may also be suitably applied when forming a film by using a substrate processing apparatus equipped with a cold-wall type process furnace.

Even when using these substrate processing apparatuses, it is possible to perform each processing using the same processing procedures and processing conditions as in the above-described embodiments and modifications, and to achieve the same effects as the above-described embodiments and modifications.

The above-described embodiments and modifications may be used in combination as appropriate. The processing procedures and processing conditions at this time may be the same as the processing procedures and processing conditions in the above-described embodiments and modifications, for example.

According to the present disclosure, it is possible to control a decomposition rate of a process gas supplied to a substrate.

While certain embodiments are described, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate comprising:
(a) processing the substrate disposed in a process space by controlling a decomposition rate of a process gas supplied into the process space based on a predetermined relationship between the decomposition rate and a residence time of the process gas.

2. The method of claim 1, wherein (a) includes:
(a1) controlling a value of the decomposition rate within a first range; and
(a2) controlling the value of the decomposition rate within a second range that is at least partially different from the first range.

3. The method of claim 1, wherein, in (a), a value of the decomposition rate is controlled to be equal to or less than a first decomposition rate by setting a value of the residence time to be equal to or less than a first time at which the value of the decomposition rate becomes the first decomposition rate.

4. The method of claim 1, wherein (a) includes:
(a1) controlling a value of the decomposition rate to be equal to or less than a first decomposition rate by setting a value of the residence time to be equal to or less than a first time at which the value of the decomposition rate becomes the first decomposition rate; and
(a2) controlling the value of the decomposition rate to be equal to or less than a second decomposition rate by setting the value of the residence time to be equal to or less than a second time at which the value of the decomposition rate becomes the second decomposition rate higher than the first decomposition rate, wherein the second time is longer than the first time.

5. The method of claim 4, wherein, in (a), (a2) is performed after (a1).

6. The method of claim 1, wherein, in (a), the process space is vacuum-exhausted before supply of the process gas to the process space is started.

7. The method of claim 1, wherein, in (a), the process space is vacuum-exhausted while the process gas is being supplied to the process space.

8. The method of claim 1, wherein, in (a), a supply amount of the process gas is maximized at start of supply of the process gas.

9. The method of claim 1, wherein, in (a), the process gas supplied to the process space is in a pressurized state.

10. The method of claim 9, wherein, in (a), the process gas supplied into the process space is pressurized to 100 to 100×10³ Pa.

11. The method of claim 1, wherein, in (a), the process gas is mixed with a low molecular weight gas with a smaller molecular weight than the process gas and supplied to the process space.

12. The method of claim 1, wherein, in (a), an internal temperature of the process space is higher than a decomposition temperature of the process gas.

13. The method of claim 1, wherein the process gas is a hexachlorodisilane gas.

14. The method of claim 1, further comprising:
(b) supplying a reactant gas that reacts with the process gas to the process space.

15. The method of claim 1, wherein, in (a), the process gas with a decomposition rate of 0% is supplied to the substrate, and then the process gas with a decomposition rate of 15% to 100% is supplied to the substrate.

16. The method of claim 1, wherein, in (a), the process gas is supplied to one substrate in an amount of 0.001 to 15 slm.

17. The method of claim 1, wherein, in (a), the process space is vacuum-exhausted.

18. A method of manufacturing a semiconductor device comprising the method of claim 1.

19. A substrate processing apparatus comprising:
a process space inside which a substrate is disposed;
a process gas supply system configured to supply a process gas to the process space; and
a controller configured to be capable of controlling the process gas supply system, so as to perform (a) controlling a decomposition rate of the process gas inside the process space based on a predetermined relationship between the decomposition rate and a residence time of the process gas.

20. A non-transitory computer-readable recording medium storing a program that causes, by a computer, a substrate processing apparatus to perform a process comprising:
(a) processing a substrate disposed in a process space by controlling a decomposition rate of a process gas supplied into the process space based on a predetermined relationship between the decomposition rate and a residence time of the process gas.
